(19) United States
(12) Patent Application Publication
(10) Pub. No.: US 2026/0074671 A1
(43) Pub. Date: Mar. 12, 2026

(54) PLATE MODE MICRO-ACOUSTIC FILTERS WITH SUSPENDED ELECTRODE FINGERS AND RELATED FABRICATION METHODS

(71) Applicant: RF360 Singapore Pte. Ltd., Singapore (SG)

(72) Inventors: Constantin Walenta, Stockdorf (DE); Soeren Zimmermann, München (DE); Willi Aigner, Moosinning (DE)

(21) Appl. No.: 18/830,086

(22) Filed: Sep. 10, 2024

(51) Int. Cl. H03H 9/13; H03H 3/02; H03H 9/54

(52) U.S. Cl. CPC H03H 9/133; H03H 3/02; H03H 9/54

(57) ABSTRACT

A micro-acoustic filter includes a piezoelectric layer having a crystalline structure that may be laterally excited in a plate mode. The piezoelectric layer is formed on a layer stack that reflects acoustic energy back toward the piezoelectric layer. Acoustic waves are excited in the piezoelectric layer by voltages provided in interdigital transducers (IDTs) on an exposed surface of the piezoelectric layer. The electrode fingers of the IDTs are spaced from the exposed surface rather than being in contact with the exposed surface of the piezoelectric layer to avoid losses and spurious modes. In some examples, the electrode fingers may be supported on one end in a cantilevered configuration to maintain a first distance from the exposed surface of the piezoelectric layer. In some examples, the electrode fingers may also be supported on a second end by a pillar extending the first distance to the exposed surface.

### TECHNICAL FIELD

The technology of the disclosure relates generally to wireless transceivers and other components that employ acoustic filters and, more specifically, to micro-acoustic filters employing plate mode resonators.

### BACKGROUND

Electronic devices may use radio-frequency (RF) signals to communicate information that enables voice communication, uploading and downloading of media (e.g., audio and video), remote control of household devices, and reception of global positioning information, for example. To transmit or receive the RF signals within a given frequency band allocated for such communications, the electronic device may use filters that pass signals within the frequency band and suppress (e.g., attenuate) jammers or noise at frequencies outside of the frequency band. It can be challenging, however, to design and manufacture a filter that provides filtering for RF applications, especially those that operate at frequencies above two (2) gigahertz (GHz) with high energy efficiency.

### SUMMARY

Aspects disclosed in the detailed description include plate mode micro-acoustic filters with suspended interdigital transducer (IDT) electrodes. Methods of fabricating plate mode micro-acoustic filters with suspended electrode fingers are also disclosed. A micro-acoustic filter includes a piezoelectric layer having a crystalline structure that may be laterally excited in a plate mode. The piezoelectric layer is formed on a layer stack that may reflect acoustic energy back toward the piezoelectric layer. Acoustic waves may be excited in the piezoelectric layer by voltages provided in IDTs disposed on an exposed surface of the piezoelectric layer. In an exemplary aspect, the electrode fingers of the IDTs are spaced from the exposed surface, rather than being in contact with the exposed surface of the piezoelectric layer, to avoid losses and spurious modes that can result from the metal electrode fingers being in contact with the piezoelectric layer. In some examples, the electrode fingers may be supported on one end in a cantilevered configuration to maintain a first distance from the exposed surface of the piezoelectric layer. In some examples, the electrode fingers may also be supported on a second end by a pillar extending the first distance to the exposed surface.

In this regard, in one aspect, a micro-acoustic filter, including a layer stack, is disclosed. The micro-acoustic filter further includes a piezoelectric layer disposed on the layer stack and includes an exposed surface opposite to the layer stack, wherein the piezoelectric layer has a crystalline structure operative to laterally excite a plate mode. The micro-acoustic filter further includes an IDT electrode structure disposed on the exposed surface of the piezoelectric layer and a first electrode structure including a plurality of first fingers and a second electrode structure including a plurality of second fingers spaced from the exposed surface.

In another aspect, a method of fabricating a micro-acoustic filter, including a layer stack, is disclosed. The method further includes forming a piezoelectric layer on the layer stack with an exposed surface opposite to the layer stack, wherein the piezoelectric layer has a crystalline structure operative to laterally excite a plate mode. The method further includes forming an IDT electrode structure disposed on the exposed surface of the piezoelectric layer and including a first electrode structure including a plurality of first fingers spaced from the exposed surface and a second electrode structure including a plurality of second fingers spaced from the exposed surface.

### BRIEF DESCRIPTION OF THE DRAWINGS

FIG. 1 illustrates an example operating environment for operating a micro-acoustic filter with electrode fingers spaced apart from the piezoelectric layer;

FIG. 2 illustrates an example wireless transceiver including at least one micro-acoustic filter with electrode fingers spaced apart from the piezoelectric layer;

FIG. 3-1 illustrates example components of a plate mode micro-acoustic filter with electrode fingers spaced apart from the piezoelectric layer;

FIG. 3-2 illustrates example Euler angles that define an orientation of a piezoelectric layer of a micro-acoustic filter that operates in a plate mode;

FIG. 4A is a perspective view of one example of a micro-acoustic filter configured to operate in a plate mode and including an interdigital transducer (IDT) electrode structure in which the electrode fingers are spaced apart from an outer surface of a piezoelectric layer on a layer stack;

FIG. 4B is a cross-sectional side view of the micro-acoustic filter in FIG. 4A, illustrating a gap between the IDT electrode fingers and the piezoelectric layer;

FIG. 5 is a flowchart of a method of making the micro-acoustic filter in FIGS. 4A and 4B;

FIG. 6A is a perspective view of an IDT having electrode fingers spaced apart from an exposed surface of a piezoelectric layer in a cantilever configuration;

FIG. 6B is a cross-sectional side view of one of the IDTs, having electrode fingers spaced apart from the piezoelectric layer in the IDT in FIG. 6A;

FIG. 7 is a cross-sectional side view of an IDT electrode finger spaced apart from the surface of the piezoelectric layer in a bridge configuration in which pillars support the electrode finger;

FIG. 8 is a cross-sectional side view of a first example of a capping layer disposed on IDTs in a plate-mode acoustic resonator, as shown in FIGS. 6A and 6B or FIG. 7;

FIG. 9 is a cross-sectional side view of a second example of a capping layer integrating IDTs for structural stability in a plate-mode acoustic resonator, as shown in FIGS. 6A and 6B or FIG. 7;

FIG. 10 is a block diagram of an exemplary processor-based system that can include plate mode micro-acoustic filters with IDT electrode structures, including IDT electrode fingers spaced apart from an outer surface of a piezoelectric layer on a layer stack to reduce energy losses and spurious modes; and

FIG. 11 is a block diagram of an exemplary wireless communication device that includes radio-frequency (RF) components that can include plate mode micro-acoustic filters with IDT electrode structures, including IDT electrode fingers spaced apart from an outer surface of a piezoelectric layer on a layer stack to reduce energy losses and spurious modes.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include plate mode micro-acoustic filters with suspended interdigital transducer (IDT) electrodes. Methods of fabricating plate mode micro-acoustic filters with suspended electrode fingers are also disclosed. A micro-acoustic filter includes a piezoelectric layer having a crystalline structure that may be laterally excited in a plate mode (e.g., the plate mode is the dominant acoustic wave mode of the micro-acoustic resonator). The piezoelectric layer is formed on a layer stack (e.g. acoustic mirror layers) that may reflect acoustic energy back toward the piezoelectric layer. Acoustic waves may be excited in the piezoelectric layer by voltages provided in IDTs disposed on an exposed surface of the piezoelectric layer. In an exemplary aspect, the electrode fingers of the IDTs are spaced from the exposed surface, rather than being in contact with the exposed surface of the piezoelectric layer, to avoid losses and spurious modes that can result from the metal electrode fingers being in contact with the piezoelectric layer. In some examples, the electrode fingers may be supported on one end in a cantilevered configuration to maintain a first distance from the exposed surface of the piezoelectric layer. In some examples, the electrode fingers may also be supported on a second end by a pillar extending the first distance to the exposed surface.

To transmit or receive radio-frequency signals within a given frequency band, an electronic device may use filters to pass signals within the frequency band and to suppress (e.g., attenuate) jammers or noise-having frequencies outside of the frequency band. Electroacoustic devices (e.g., “acoustic filters”) can be used to filter high-frequency signals in many applications, such as those with frequencies that are greater than 100 megahertz (MHz). An acoustic filter is tuned to pass certain frequencies (e.g., frequencies within its passband) and attenuate other frequencies (e.g., frequencies that are outside of its passband). In an acoustic resonator or an acoustic filter, an electrical signal having a time-varying voltage is applied to an electrode structure to create an electric field of varying intensity in a piezoelectric material. The piezoelectric material transforms the varying electric field into an acoustic wave. The acoustic wave induces an electric field in the piezoelectric material and the electrode structure detects the electric field and transforms or converts it to an electrical output signal.

The resonant frequencies of acoustic resonators are determined by the dimensions of the acoustic resonator and/or electrode structure. Since higher frequency signals have shorter wavelengths, smaller dimensions are needed. Accordingly, such frequencies can make it challenging to design a micro-acoustic filter that can provide filtering for signals at higher frequencies, such as those used with Wi-Fi^{®} at 2.4 gigahertz (GHz) frequencies, at 5 GHz frequencies, at frequencies greater than 5 GHz, at sub-6 GHz frequencies, at frequencies between 6 and 18 GHz, and/or at frequencies greater than or equal to 10 GHz. In particular, it can be challenging to design a filter that is affordable and can realize a target level of performance in terms of resonance quality factors, electromechanical coupling, power durability, insertion loss, and spurious-mode suppression.

To address these challenges, some micro-acoustic filters implement a laterally-excited plate mode in the piezoelectric layer. The laterally-excited plate-mode micro-acoustic filter can realize a target level of performance in terms of electromechanical coupling, insertion loss, and quality factors at higher frequencies. And IDT electrode dimensions may be feasible to manufacture even at higher frequencies. The performance of these filters, however, can be negatively impacted by the electrodes of an IDT in contact with the surface of the piezoelectric layer. The metal electrode disposed directly on the piezoelectric layer interferes with the acoustic waves propagating in the piezoelectric layer, impeding wave propagation and causing a loss of some of the energy in an input signal, which reduces the Q factor of the device. While using large spacings between IDTs represents one way to mitigate spurious modes and to reduce viscoelastic losses in the IDTs, the density of the static capacitance spanned between IDTs at large spacings (i.e., large pitches) would be insufficient to achieve a required level of miniaturization of the micro-acoustic filter. To avoid the energy loss caused by having the IDT electrodes in direct contact with a surface of the piezoelectric layer and to avoid the miniaturization limitations they would impose, a plate-mode resonator in which the electrodes of the IDTs are spaced from the piezoelectric layer is disclosed. The IDT electrodes may be suspended above a surface of the piezoelectric layer, employing either a cantilevered structure having no contact with the piezoelectric layer or a bridge structure including support pillars with a small footprint to minimize acoustic impact. The intensity of the electric field created by the voltage difference between electrodes on opposite sides of the IDT decreases only slightly across the gap between the IDT electrodes and the piezoelectric layer, and this loss is more than offset by avoiding the limitations caused by having IDT electrodes in direct contact with the piezoelectric layer.

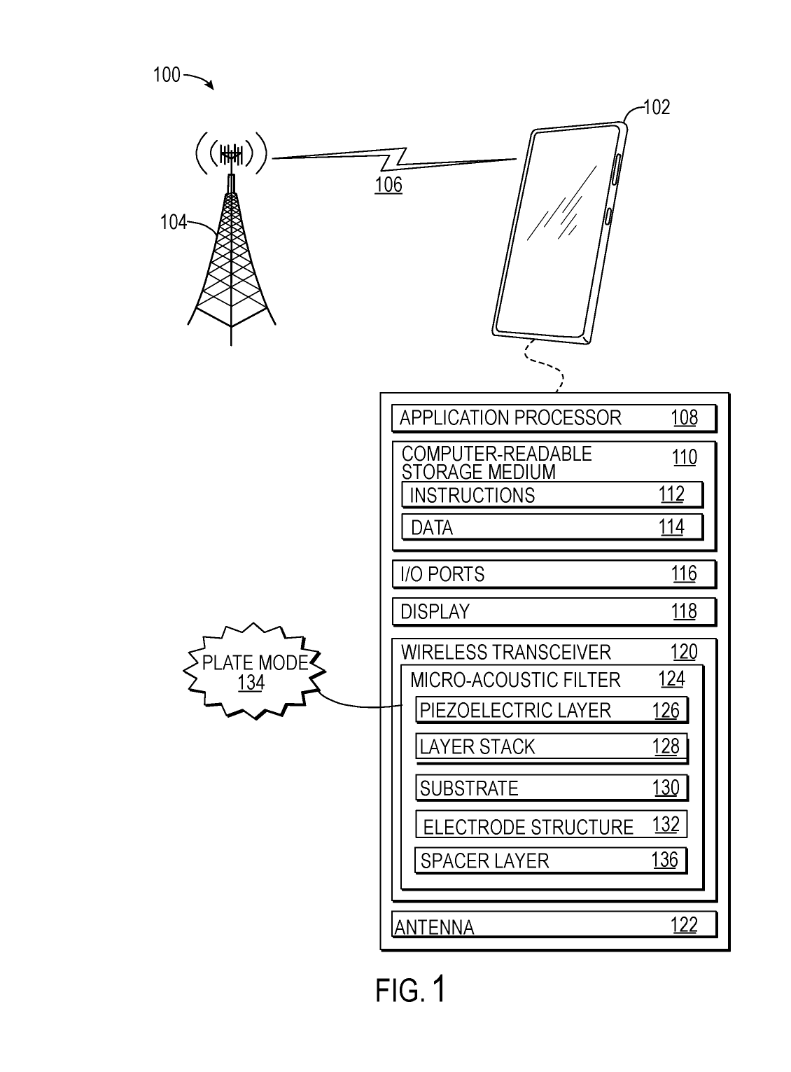

FIG. 1 illustrates an example environment 100 for operating a plate-mode micro-acoustic filter with IDT electrodes separated from an outer (e.g., top) surface of a piezoelectric layer on a layer stack, including a substrate layer. In the environment 100, a computing device 102 communicates with a base station 104 through a wireless communication link 106 (wireless link 106). In this example, the computing device 102 depicted is a smartphone. However, the computing device 102 can be implemented as any suitable computing or electronic device, such as a modem, a cellular base station, a broadband router, an access point, a cellular phone, a gaming device, a navigation device, a media device, a laptop computer, a desktop computer, a tablet computer, a wearable computer, a server, a network-attached storage (NAS) device, a smart appliance or other internet of things (IoT) device, a medical device, a vehicle-based communication system, a radar, a radio apparatus, and so forth. Use of a micro-acoustic filter is not limited to wireless communication as a micro-acoustic filter can be applied in any technological field where such filtering is useful.

The base station 104 communicates with the computing device 102 via the wireless link 106, which can be implemented as any suitable type of wireless link. Although depicted as a tower of a cellular network, the base station 104 can represent or be implemented as another device, such as a satellite, a server device, a terrestrial television broadcast tower, an access point, a peer-to-peer device, a mesh network node, and so forth. Therefore, the computing device 102 may communicate with the base station 104 or another device via a wireless connection.

The wireless link 106 can include a downlink of data or control information communicated from the base station 104 to the computing device 102, an uplink of other data or control information communicated from the computing device 102 to the base station 104, or both a downlink and an uplink. The wireless link 106 can be implemented using any suitable communication protocol or standard, such as 2nd-generation (2G), 3rd-generation (3G), 4th-generation (4G), 5th-generation (5G), or 6th-generation (6G) cellular; IEEE 802.11 (e.g., Wi-Fi^{®}); IEEE 802.15 (e.g., Bluetooth^{®}); IEEE 802.16 (e.g., WiMAX^{®}); and so forth. In some implementations, the wireless link 106 may wirelessly provide power and the base station 104 or the computing device 102 may comprise a power source.

As shown, the computing device 102 includes an application processor 108 and a computer-readable storage medium 110 (CRM 110). The application processor 108 can include any type of processor, such as a multi-core processor, that executes processor-executable code stored by the CRM 110. The CRM 110 can include any suitable type of data storage media, such as volatile memory (e.g., random access memory (RAM)), non-volatile memory (e.g., Flash memory), optical media, magnetic media (e.g., disk), and so forth. In the context of this disclosure, the CRM 110 is implemented to store instructions 112, data 114, and other information of the computing device 102 and thus does not include transitory propagating signals or carrier waves.

The computing device 102 can also include input/output ports 116 (I/O ports 116) and a display 118. The I/O ports 116 enable data exchanges or interaction with other devices, networks, or users. The I/O ports 116 can include serial ports (e.g., universal serial bus (USB) ports), parallel ports, audio ports, infrared (IR) ports, user interface ports such as a touchscreen, and so forth. The display 118 presents graphics of the computing device 102, such as a user interface associated with an operating system, program, or application. Alternatively, or additionally, the display 118 can be implemented as a display port or virtual interface, through which the graphical content of the computing device 102 is presented.

A wireless transceiver 120 of the computing device 102 provides connectivity to respective networks and other electronic devices connected therewith. The wireless transceiver 120 can facilitate communication over any suitable type of wireless network, such as a wireless local area network (WLAN), peer-to-peer (P2P) network, mesh network, cellular network, ultra-wideband (UWB) network, wireless wide-area-network (WWAN), and/or wireless personal-area-network (WPAN). In the context of the example environment 100, the wireless transceiver 120 enables the computing device 102 to communicate with the base station 104 and the networks connected therewith. However, the wireless transceiver 120 can also enable the computing device 102 to communicate “directly” with other devices or networks.

The wireless transceiver 120 includes circuitry and logic for transmitting and receiving communication signals via an antenna 122. Components of the wireless transceiver 120 can include amplifiers, switches, mixers, analog-to-digital converters, filters, and so forth for conditioning the communication signals (e.g., for generating or processing signals). The wireless transceiver 120 can also include logic to perform in-phase/quadrature (I/Q) operations, such as synthesis, encoding, modulation, decoding, demodulation, and so forth. In some cases, components of the wireless transceiver 120 are implemented as separate transmitter and receiver entities. Additionally, or alternatively, the wireless transceiver 120 can be realized using multiple or different sections to implement respective transmitting and receiving operations (e.g., separate transmit and receive chains). In general, the wireless transceiver 120 processes data and/or signals associated with communicating data of the computing device 102 over the antenna 122.

In the example shown in FIG. 1, the wireless transceiver 120 includes at least one micro-acoustic filter 124 (e.g., an acoustic filter, a plate-mode acoustic-wave filter, or a membrane-type filter). In some implementations, the wireless transceiver 120 includes multiple micro-acoustic filters 124, which can be formed from micro-acoustic resonators arranged in series, in parallel, in a ladder structure, in a lattice structure, or some combination thereof. The micro-acoustic filter 124 includes at least one piezoelectric layer 126 disposed on a layer stack 128 on a substrate 130 and at least one electrode structure 132 disposed on and spaced from the piezoelectric layer 126.

Although the micro-acoustic filter 124 can be any type of micro-acoustic filter, the technique of employing the electrode structure 132 separated from (e.g., suspended above) an exposed surface of the piezoelectric layer 126 to laterally excite the piezoelectric layer 126 in a plate mode 134 can be particularly advantageous for reducing acoustic losses that would otherwise occur due to having the electrode structure 132 in direct contact with the piezoelectric layer 126. The plate mode 134 can be a first order antisymmetric Lamb mode (e.g., an A1 mode). Other order modes are also possible. The plate mode 134 can be referred to as a laterally-excited plate mode, as further explained below.

The piezoelectric layer 126 has a crystalline structure operative to laterally excite the plate mode 134. The laterally-excited plate mode 134 forms an acoustic wave that causes different portions (e.g., an upper portion and a lower portion) of the piezoelectric layer 126 to move in opposite directions along a horizontal dimension. In other words, the laterally-excited plate mode 134 causes displacement and elongation to occur along the horizontal dimension while the propagation of the wavefronts occurs along a vertical dimension of the piezoelectric layer 126. The wavefronts are vertically reflected at the free surface of the piezoelectric layer 126. The plate mode 134 is a quasi-stationary mode with approximately a zero-group velocity in the lateral direction in the case of large pitches significantly exceeding a thickness of the piezoelectric layer 126.

The electrode structure 132 is positioned on the piezoelectric layer 126, which is disposed on the layer stack 128, including the substrate 130. In an exemplary aspect, the electrode structure 132 may be spaced from the piezoelectric layer 126 and is still able to induce an electric field in the piezoelectric layer 126 across the (e.g., air) gap. In some examples, at least a portion of the electrode structure 132 may not be coupled to the piezoelectric layer 126. In such examples, the micro-acoustic filter 124 may include at least one spacer layer 136, which spaces or separates the electrode structure 132 apart from the piezoelectric layer 126. As such, the electrode structure 132 is, at least locally, physically separated from the piezoelectric layer 126 and may include a gap between the electrode structure 132 and the piezoelectric layer 126.

With these improvements, the micro-acoustic filter 124 can be designed to support frequency ranges above 2 GHz, including frequencies between approximately 2 and 20 GHz. For example, the micro-acoustic filter 124 can be designed to have a resonance frequency between approximately 4 and 18 GHz, between approximately 7.5 and 17 GHz, or equal to approximately 4, 5, 6, 10, 13, 15, 17, or 20 GHz. In general, the term “approximately” can mean that any of the frequencies can be within ± 10% of a specified value or less (e.g., within ± 5%, ± 3%, or ± 2% of a specified value). The micro-acoustic filter 124 is further described with respect toFIG. 2.

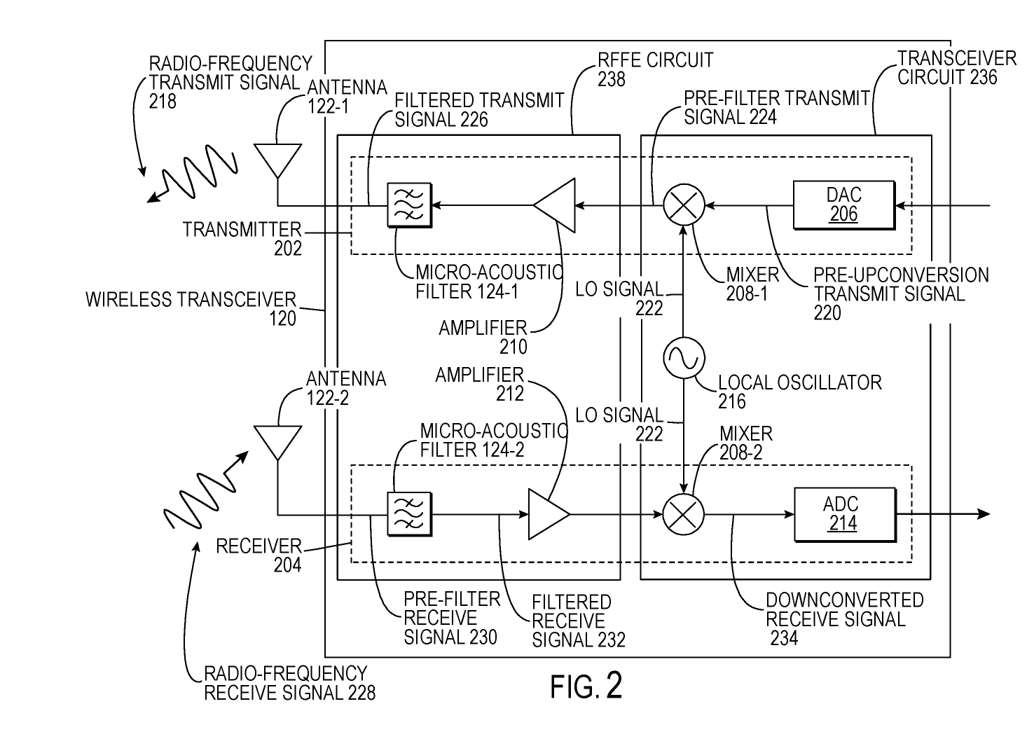

FIG. 2 illustrates an example of the wireless transceiver 120. In the depicted configuration, the wireless transceiver 120 includes a transmitter 202 and a receiver 204, which are respectively coupled to a first antenna 122-1 and a second antenna 122-2. In other implementations, the transmitter 202 and the receiver 204 can be connected to a same antenna through a duplexer (not shown). The transmitter 202 is shown to include at least one digital-to-analog converter 206 (DAC 206), at least one first mixer 208-1, at least one amplifier 210 (e.g., a power amplifier), and at least one first micro-acoustic filter 124-1. The receiver 204 includes at least one second micro-acoustic filter 124-2, at least one amplifier 212 (e.g., a low-noise amplifier), at least one second mixer 208-2, and at least one analog-to-digital converter 214 (ADC 214). The first mixer 208-1 and the second mixer 208-2 are coupled to a local oscillator 216. Although not explicitly shown, the DAC 206 of the transmitter 202 and the ADC 214 of the receiver 204 can be coupled to the application processor 108 (of FIG. 1) or another processor associated with the wireless transceiver 120 (e.g., a modem).

In some implementations, the wireless transceiver 120 is implemented using multiple circuits (e.g., multiple integrated circuits), such as a transceiver circuit 236 and a radio-frequency front-end (RFFE) circuit 238. As such, the components that form the transmitter 202 and the receiver 204 are distributed across these circuits. As shown in FIG. 2, the transceiver circuit 236 includes the DAC 206 of the transmitter 202, the mixer 208-1 of the transmitter 202, the mixer 208-2 of the receiver 204, and the ADC 214 of the receiver 204. In other implementations, the DAC 206 and the ADC 214 can be implemented on another separate circuit that includes the application processor 108 or the modem. The RFFE circuit 238 includes the amplifier 210 of the transmitter 202, the micro-acoustic filter 124-1 of the transmitter 202, the micro-acoustic filter 124-2 of the receiver 204, and the amplifier 212 of the receiver 204.

During transmission, the transmitter 202 generates a radio-frequency transmit signal 218, which is transmitted using the antenna 122-1. To generate the radio-frequency transmit signal 218, the DAC 206 provides a pre-upconversion transmit signal 220 to the first mixer 208-1. The pre-upconversion transmit signal 220 can be a baseband signal or an intermediate-frequency signal. The first mixer 208-1 upconverts the pre-upconversion transmit signal 220 using a local oscillator (LO) signal 222 provided by the local oscillator 216. The first mixer 208-1 generates an upconverted signal, which is referred to as a pre-filter transmit signal 224. The pre-filter transmit signal 224 can be a radio-frequency signal and include some noise or unwanted frequencies, such as a harmonic frequency. The amplifier 210 amplifies the pre-filter transmit signal 224 and passes the amplified pre-filter transmit signal 224 to the first micro-acoustic filter 124-1.

The first micro-acoustic filter 124-1 filters the amplified pre-filter transmit signal 224 to generate a filtered transmit signal 226. As part of the filtering process, the first micro-acoustic filter 124-1 attenuates the noise or unwanted frequencies within the pre-filter transmit signal 224. The transmitter 202 provides the filtered transmit signal 226 to the antenna 122-1 for transmission. The transmitted filtered transmit signal 226 is represented by the radio-frequency transmit signal 218.

During reception, the antenna 122-2 receives a radio-frequency receive signal 228 and passes the radio-frequency receive signal 228 to the receiver 204. The second micro-acoustic filter 124-2 accepts the received radio-frequency receive signal 228, which is represented by a pre-filter receive signal 230. The second micro-acoustic filter 124-2 filters any noise or unwanted frequencies within the pre-filter receive signal 230 to generate a filtered receive signal 232.

The amplifier 212 of the receiver 204 amplifies the filtered receive signal 232 and passes the amplified filtered receive signal 232 to the second mixer 208-2. The second mixer 208-2 downconverts the amplified filtered receive signal 232 using the LO signal 222 to generate the downconverted receive signal 234. The ADC 214 converts the downconverted receive signal 234 into a digital signal, which can be processed by the application processor 108 or another processor associated with the wireless transceiver 120 (e.g., the modem).

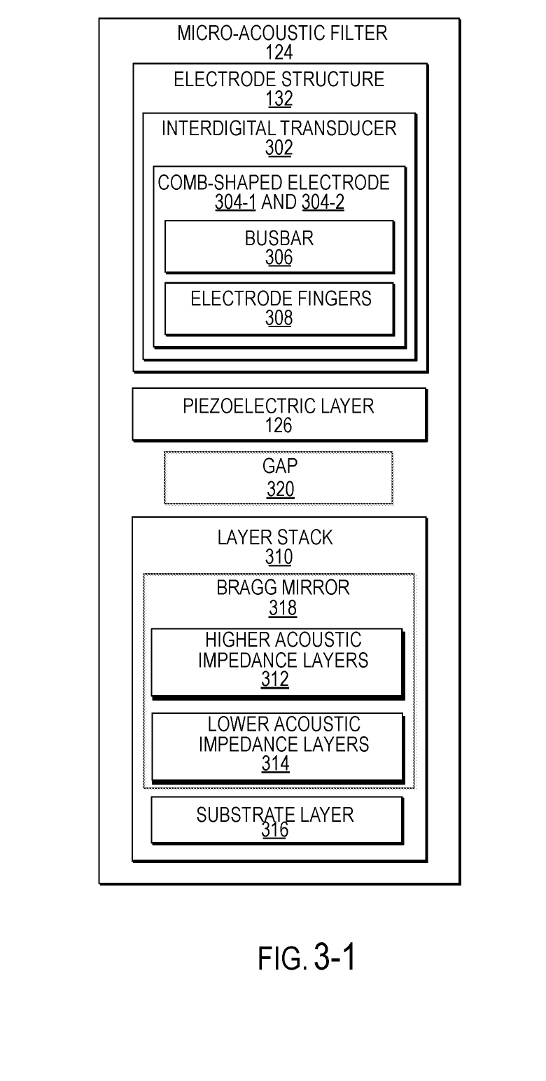

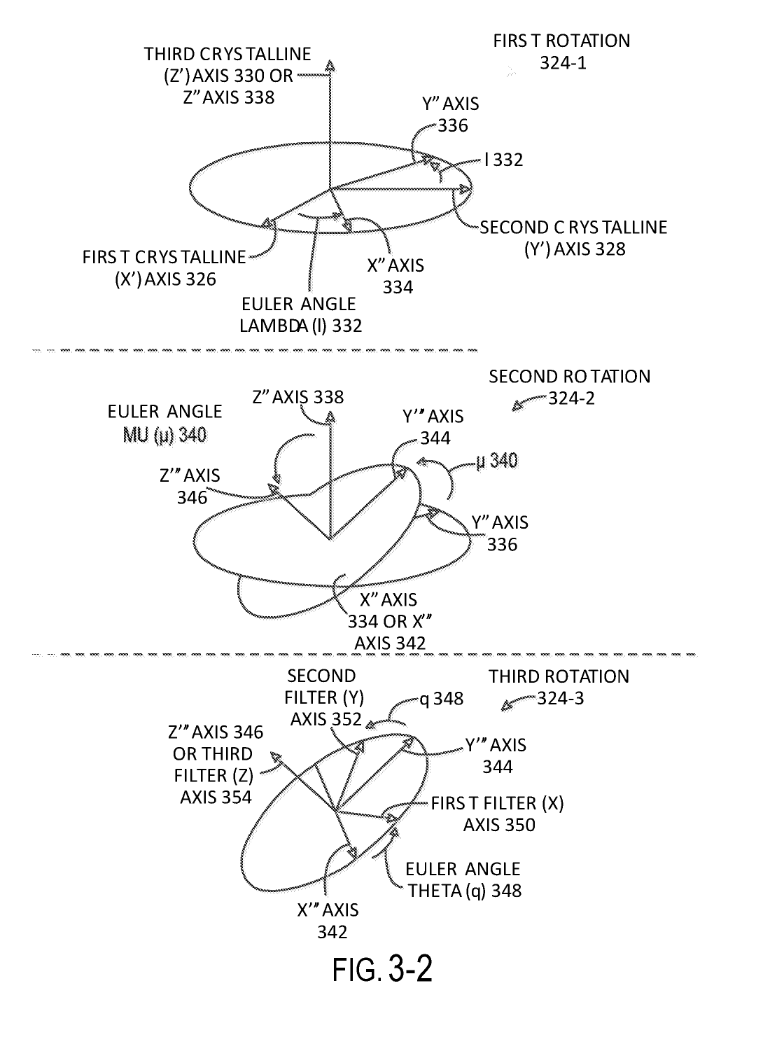

FIG. 2 illustrates one example configuration of the wireless transceiver 120. Other configurations of the wireless transceiver 120 can support multiple frequency bands and share an antenna 122 across multiple transceivers. One of ordinary skill in the art can appreciate the variety of other configurations for which micro-acoustic filters 124 may be included. For example, the micro-acoustic filters 124 can be integrated within duplexers or diplexers of the wireless transceiver 120. Example implementations of the micro-acoustic filter 124-1 or 124-2 are further described with respect to FIG. 3-1.

FIG. 3-1 illustrates example components of the micro-acoustic filter 124. In the depicted configuration, the micro-acoustic filter 124 includes the piezoelectric layer 126 and the electrode structure 132. In example implementations, the piezoelectric layer 126 can be implemented using a variety of different materials that exhibit piezoelectric properties (e.g., can transfer mechanical energy into electrical energy or electrical energy into mechanical energy). Example types of material include lithium niobate (LiNbO₃), lithium tantalate (LiTaO₃), or some combination thereof. In general, the material that forms the piezoelectric layer 126 may have a crystalline structure. This crystalline structure is defined by an ordered arrangement of particles (e.g., atoms, ions, or molecules). The orientation of the crystalline structure of the piezoelectric layer 126 can be defined by Euler angles lambda (λ), mu (µ), and theta (θ).

In some aspects, the material and crystalline structure of the piezoelectric layer 126 is selected such that the plate mode 134 can be laterally excited within the piezoelectric layer 126. Consider two examples in which the piezoelectric layer 126 is formed using lithium niobate. In a first example implementation, the lithium niobate material is cut such that a value of the Euler angle mu (µ) is approximately 32.5° and values of the Euler angles lambda (λ) and theta (θ) are approximately 0° (or at least one symmetrical equivalent thereof). In a second example implementation, the lithium niobate material is cut such that a value of the Euler angle theta (θ) is approximately 90° and values of the Euler angles lambda (λ) and mu (µ) are approximately 0° (or at least one symmetrical equivalent thereof). In general, the term “approximately” can mean that any of the angles can be within ± 10% of a specified value or less (e.g., within ± 5%, ± 3%, or ± 2% of a specified value).

In another example, the piezoelectric layer 126 is formed using lithium tantalate. In this case, the lithium tantalate material is cut such that a value of the Euler angle mu (µ) is approximately 36° and values of the Euler angles lambda (λ) and theta (θ) are approximately 0° (or at least one symmetrical equivalent thereof). In general, the term “approximately” can mean that any of the angles can be within ± 10% of a specified value or less (e.g., within ± 5%, ± 3%, or ± 2% of a specified value). The Euler angles are further described with respect to FIG. 3-2.

For the plate mode 134, a resonance frequency of the micro-acoustic filter 124 is determined, at least in part, by a thickness of the piezoelectric layer 126. To realize a resonance frequency between 4 and 15 GHz, the thickness of the piezoelectric layer 126 can be between approximately 100 and 400 nanometers (nm), for instance. Generally speaking, the thickness of the piezoelectric layer 126 and the resonance frequency are inversely related. In other words, decreasing the thickness of the piezoelectric layer 126 increases the resonance frequency of the micro-acoustic filter 124, while increasing the thickness of the piezoelectric layer 126 decreases the resonance frequency of the micro-acoustic filter 124.

The electrode structure 132 comprises an electrically conductive material, such as metal, and can include one or more layers. The one or more layers can include one or more electrically conductive layers and can optionally include one or more adhesion layers. As an example, the electrically conductive layers can be composed of aluminum (Al), copper (Cu), silver (Ag), gold (Au), tungsten (W), silicon (Si), or some combination or doped version thereof. The adhesion layers can be composed of chromium (Cr), titanium (Ti), molybdenum (Mo), or some combination thereof.

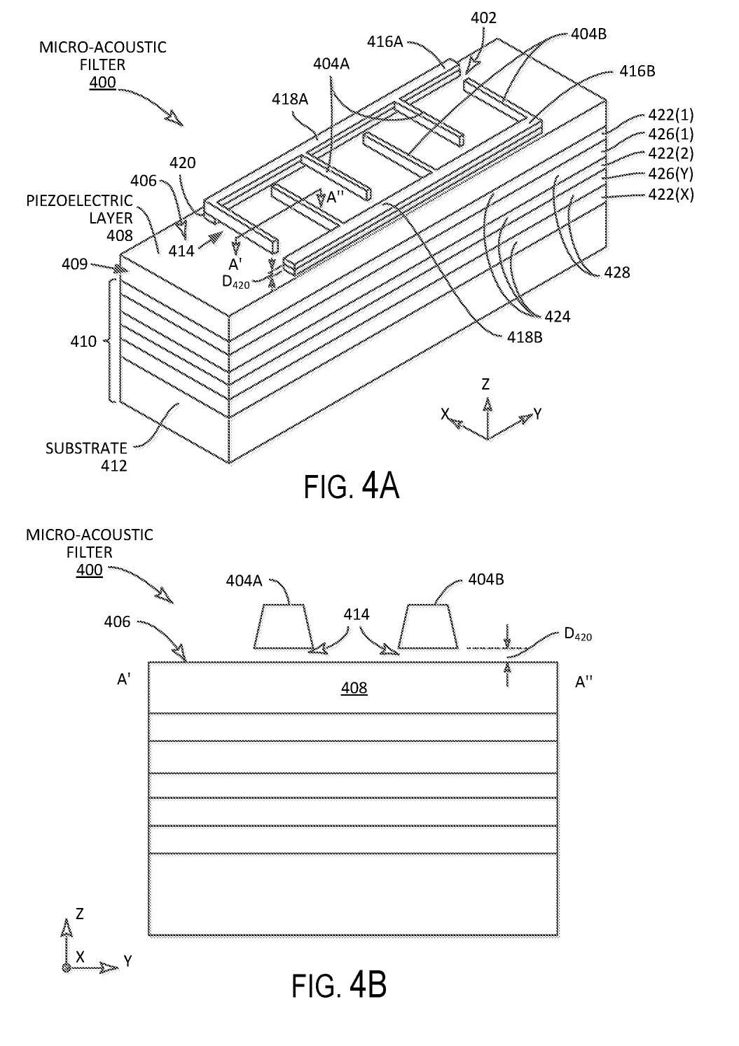

The electrode structure 132 can include one or more interdigital transducers 302. The interdigital transducer 302 converts an electrical signal into an acoustic wave and converts the acoustic wave into a filtered electrical signal. The interdigital transducer 302 includes at least two comb-shaped electrodes 304-1 and 304-2. Each comb-shaped electrode 304-1 and 304-2 includes a busbar 306 (e.g., a conductive segment or rail) and multiple fingers 308 (e.g., electrode fingers). An example of interdigital transducer 302 is further described with respect to FIG. 4. Although not explicitly shown, the interdigital transducer 302 can also include two or more reflectors. In an example implementation, the electrode structure 132 in the interdigital transducer 302 is arranged between two reflectors.

The micro-acoustic filter 124 also includes a substrate stack 310 (also referred to as layer stack 310), which represents an example implementation of the substrate 130 of FIG. 1. The layer stack 310 includes alternating higher acoustic impedance layers 312 and lower acoustic impedance layers 314 on a substrate layer 316. The substrate layer 316 is composed of non-conducting material that provides isolation. Example materials include silicon (Si), silicon dioxide (SiO₂), silicon carbide (SiC), sapphire, glass, or some combination or doped version thereof. In some implementations, the substrate layer 316 is composed of multiple layers. The multiple layers can be formed using the same material or different materials.

The alternating higher acoustic impedance layers 312 and lower acoustic impedance layers 314 may be provided to form a Bragg mirror 318 (e.g., acoustic mirror). The piezoelectric layer 126 may be disposed directly or indirectly (e.g., without or with an intervening layer(s)) on the layer stack 310.

The electrode structure 132 may be spaced from (e.g., vertically) the piezoelectric layer 126 by the at least one spacer layer 136. Specifically, the busbar 306 and the fingers 308 of the electrode structure 132 extend parallel to the piezoelectric layer 126 and may be spaced from the piezoelectric layer 126 by a layer of a material forming the at least one spacer layer 136. However, the least one spacer layer 136 is formed under the busbar 306 and does not extend between the electrode fingers 308 and the piezoelectric layer 126. Thus, the electrode fingers 308 are at a distance from the piezoelectric layer 126 based on a height (in a direction orthogonal to the piezoelectric layer 126) of a gap 320 between the electrode fingers 308 and the piezoelectric layer 126 that corresponds to a thickness of the at least one spacer layer 136. In some examples, the electrode fingers 308 are cantilevered over (without touching) the piezoelectric layer 126, and in other examples, the electrode fingers 308 may be supported at one end by the busbar 306 and also supported at the other end. Eliminating or at least reducing contact between the electrode fingers 308 and the piezoelectric layer 126 by providing the gap 326 reduces losses and spurious modes in the micro-acoustic filter 124.

FIG. 3-2 illustrates example Euler angles that define an orientation of the piezoelectric layer 126 relative to a crystalline structure of the material that forms the piezoelectric layer 126. In this example, the material that forms the piezoelectric layer 126 includes lithium niobate and/or lithium tantalate. A first crystalline (X’) axis 326, a second crystalline (Y’) axis 328, and a third crystalline (Z’) axis 330 are fixed along crystallographic axes of a lithium niobate crystal. A first rotation 324-1 is applied to rotate the first crystalline X’ axis 326 and the second crystalline Y’ axis 328 about the third crystalline Z’ axis 330. In particular, the first rotation 324-1 rotates the first crystalline X’ axis 326 in a direction of the second crystalline Y’ axis 328. The angle associated with the first rotation 324-1 characterizes one of the Euler angles, which is represented by Euler angle lambda (λ) 332. The resulting rotated axes are represented by a new set of axes: an X’’ axis 334, a Y’’ axis 336, and a Z’’ axis 338. As shown in FIGS. 3-2, the third crystalline Z’ axis 330 remains unchanged by the first rotation 324-1 such that the third crystalline Z’ axis 330 is equal to the Z’’ axis 338.

In a second rotation 324-2, the Y’’ axis 336 and the Z’’ axis 338 are rotated about the X’’ axis 334 by another Euler angle, which is represented by Euler angle mu (µ) 340. In this case, the Y’’ axis 336 is rotated in the direction of the Z’’ axis 338. The resulting rotated axes are represented by a new set of axes: an X’’’ axis 342, a Y’’’ axis 344, and a Z’’’ axis 346. As shown in FIG. 3-2, the X’’ axis 334 remains unchanged by the second rotation 324-2 such that the X’’ axis 334 is equal to the X’’’ axis 342.

In a third rotation 324-3, the X’’’ axis 342 and the Y’’’ 344 axis are rotated about the Z’’’ axis 346 by an additional Euler angle, which is represented by Euler angle theta (θ) 348. In this case, the X’’’ axis 342 is rotated in the direction of the Y’’’ axis 344. The resulting rotated axes are represented by a first filter (X) axis 350, a second filter (Y) axis 352, and a third filter (Z) axis 354, which respectively correspond to the X-axis, the Y-axis, and the Z-axis of FIG. 4A. As shown in FIGS. 3-2, the Z’’’ axis 346 remains unchanged by the third rotation 324-3 such that the Z’’’ axis 346 is equal to the third filter Z axis 354. The micro-acoustic filter 124 is further described with respect to FIG. 4A.

FIG. 4A is a perspective view of one example of a micro-acoustic filter 400 configured to operate in a plate mode and including an interdigital transducer (IDT) electrode structure 402 including a first electrode 416A and a second electrode 416B, having first electrode fingers 404A and second electrode fingers 404B, respectively, spaced apart from an outer surface 406 of a piezoelectric layer 408, which is formed on a layer stack 410 that includes a substrate 412. The first electrode 416A is configured to couple to a first voltage, and the second electrode 416B is configured to couple to a second voltage. The IDT electrode structure 402 may be formed of any appropriate conductive material(s), such as metals (e.g., aluminum, copper, titanium, platinum, and/or alloys of such metals).

One side of the piezoelectric layer 408 is disposed on the layer stack 410. In other words, a piezoelectric material 409 of the piezoelectric layer 408 may be disposed directly on top of the layer stack 410 in the first, Z-axis direction with the outer surface 406 opposite to the layer stack 410. Alternatively, there may be at least one intervening layer between the piezoelectric material 409 and the layer stack 410. In either of such examples, the outer surface 406 of the piezoelectric layer 408 is exposed and extends in the second, X-axis direction and the third, Y-axis direction.

The first and second electrode fingers 404A, 404B (“electrode fingers 404A, 404B”) of the first and second electrodes 416A, 416B are spaced from the outer surface 406 in the first, Z-axis direction orthogonal to the outer surface 406 of the piezoelectric layer 408 by a gap 414, which may be filled with air or another gas. Spacing the electrode fingers 404A, 404B from the piezoelectric layer 408 by an air gap 414 improves the frequency response and quality factor Q of the plate-mode micro-acoustic filter 400 by reducing spurious modes and energy losses that would otherwise be caused where the metal electrode fingers 404A, 404B contact the acoustically-excited piezoelectric layer 408.

The first electrode 416A and the second electrode 416B have similar or identical structures disposed in complementary positions. The first electrode 416A includes busbar 418A extending in a second, X-axis direction parallel to the piezoelectric layer 408, and the first electrode fingers 404A extending from the busbar 418A in a third, Y-axis direction parallel to the outer surface 406 of the piezoelectric layer 408. The second electrode 416B, includes busbar 418B extending in the second, X-axis direction, and the second electrode fingers 404B, extending from the busbar 418B in the third, Y-axis direction parallel to the piezoelectric layer 408. The busbars 418A, 418B may be spaced from the piezoelectric layer 408 at a distance D_{420,} which may be determined by a thickness of the spacer layer 420. Thus, the gap 414 in this example has a height in the first, Z-axis direction corresponding to (e.g., equal to) the thickness D₄₂₀ of the spacer layer 420.

The layer stack 410 includes layers 422(1)-422(X) (where X=3 in this example but may be 2 or 4) of a low-acoustic impedance material 424, such as amorphous silicon dioxide (SiO₂), fluorine-doped silicon dioxide, or silicon dioxide doped with any other material, alternating with layers 426(1)-426(Y) (where Y=X or X-1) (e.g., Y= 2, 3, or 4) of a high-acoustic impedance material 428, such as hafnium oxide (HfO₂), Hafnium nitride, hafnium oxynitrides and aluminum nitride. The combination of the layers 422(1)-422(X) and 426(1)-426(Y) are provided to reflect acoustic energy back to the piezoelectric layer 408 and may be referred to collectively as a “Bragg” mirror. The Bragg mirror may have a total of four (4) to eight (8) layers as discussed above. The substrate 412 may be a semiconductor material, such as silicon (Si), for example.

FIG. 4B is a side view of a partial cross-section A’-A” of the micro-acoustic filter 400 in FIG. 4A more clearly illustrating the gap 414 spacing the IDT electrode fingers 404A, 404B the distance D₄₂₀ from the outer surface 406 of the piezoelectric layer 408. The distance D₄₂₀ may be in a range of one (1) nanometer (nm) to one hundred (100) nm, more specifically in a range from twenty-five (25) nm to thirty-five (35) nm, and even more specifically, thirty (30) nm. In this example, the gap 414 between the electrode fingers 404A, 404B, and the piezoelectric layer 408 may be filled with air or another gas. In some examples, another fluid or other material, such as a material that does not conduct the acoustic energy from the piezoelectric layer 408, may be employed in the gap 414.

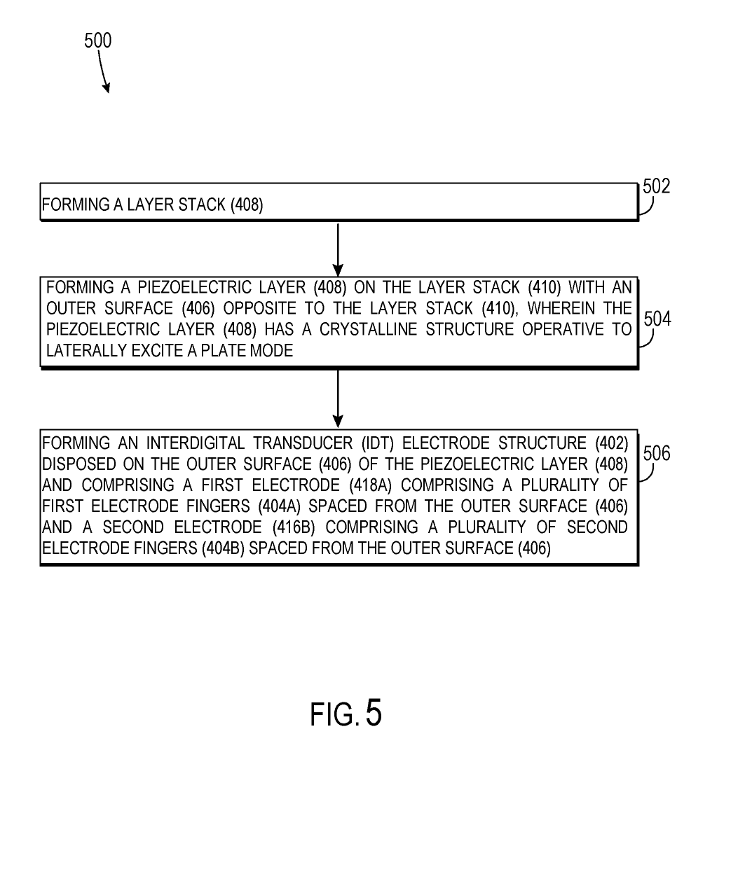

FIG. 5 is a flowchart of a method 500 of making the micro-acoustic filter in FIGS. 4A and 4B. The method includes forming a layer stack 410 (block 502), forming a piezoelectric layer 408 on the layer stack 410 with an outer surface 406 opposite to the layer stack 410, wherein the piezoelectric layer 408 has a crystalline structure operative to laterally excite a plate mode (block 504) – in some implementations forming a layer stack 410 may include forming an acoustic mirror on a substrate; and forming an interdigital transducer (IDT) electrode structure 402 disposed on the outer surface 406 of the piezoelectric layer 408 and comprising a first electrode 416A comprising a plurality of first electrode fingers 404A spaced from the outer surface 406 and a second electrode 416B comprising a plurality of second electrode fingers 404B spaced from the outer surface 406 (block 506).

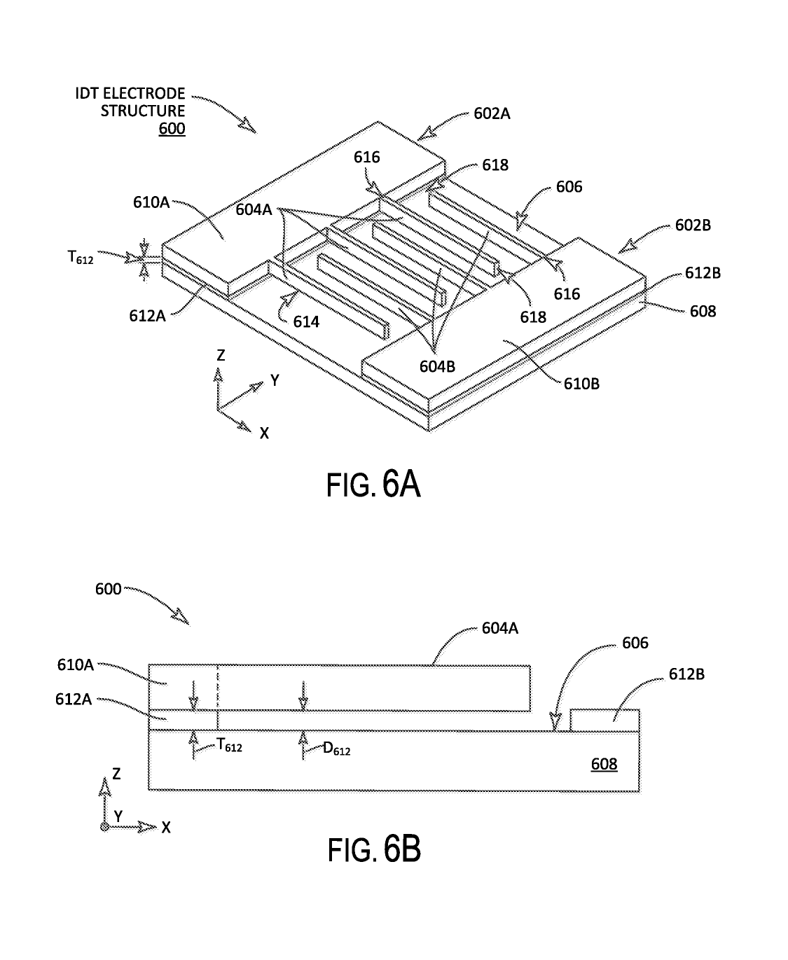

FIG. 6A is a perspective view of an IDT electrode structure 600 including a first electrode 602A including first electrode fingers 604A and a second electrode 602B including second electrode fingers 604B, where the electrode fingers 604A, 604B are spaced apart from an outer surface 606 of a piezoelectric layer 608 in a cantilevered configuration. The first electrode 602A and the second electrode 602B include busbars 610A and 610B, respectively, from which the first and second electrode fingers 604A, 604B extend. The busbars 610A, 610B are disposed on spacer layers 612A, 612B having a thickness T₆₁₂. Consequently, the first and second electrode fingers 604A, 604B extend parallel to the outer surface 606 and are spaced a distance D₆₁₂ (see FIG. 6B) from the outer surface 606 in a first, Z-axis direction orthogonal to the outer surface 606, where the distance D₆₁₂ may be equal to the thickness T₆₁₂ of the spacer layers 612A, 612B. The distance D₆₁₂ also has a height of a gap 614 in the first, Z-axis direction. The configuration in FIG. 6A may be referred to as “cantilevered” at least because a first end 616 of the first and second electrode fingers 604A, 604B is supported by the busbars 610A, 610B and the first and second electrode fingers 604A, 604B extend parallel to the outer surface 606 (e.g., horizontally), but a second end 618 of the first and second electrode fingers 604A, 604B is not supported. The electrode structure 600 and the piezoelectric layer 608 may be the IDT electrode structure 402 and the piezoelectric layer 408 in FIGS. 4A and 4B and disposed on a layer stack, such as the layer stack 410.

In some examples of an IDT electrode structure similar to the IDT electrode structure 600 in FIG. 6A, the spacer layers 612A, 612B are formed from a spacer layer (not shown) that is present on the outer surface 606 during formation of the first and second electrode fingers 604A, 604B. In such examples, the spacer layer is removed (e.g., etched away) from under the first and second electrode fingers 604A, 604B to leave the gap 614 but not removed from under the busbars 610A, 610B.

In an alternative example, the spacer layers 612A, 612B may be omitted and the busbars 610A, 610B may be directly on the outer surface 606 of the piezoelectric layer 608. In this example, the busbars 610A, 610B may be formed having a greater thickness while the first and second electrode fingers 604A, 604B would remain the same as the example shown in FIG. 6A. Fabrication of such examples may be achieved by masking a spacer layer to remove the spacer layer in the areas of the outer surface 606 on which the busbars 610A, 610B are to be formed. The electrode material (e.g., metal) may be deposited directly on the piezo electric material in the areas of the busbars 610A, 610B and also on the spacer layer to form the first and second electrode fingers 604A, 604B. The spacer layer is subsequently removed from beneath the first and second electrode fingers 604A, 604B to leave the gap 614.

FIG. 6B is a cross-sectional side view of one of the first electrode fingers 604A spaced apart from the outer surface 606 of the piezoelectric layer 608 in the IDT electrode structure 600 in FIG. 6A. FIG. 6B shows the busbar 610A disposed on the spacer layer 612A and the first electrode finger 604A extending parallel to the outer surface 606 of the piezoelectric layer 608 and spaced from the outer surface 606 at a distance D₆₁₂ equal to or based on the thickness T₆₁₂. In some examples, the distance D₆₁₂ may be greater than or less than the thickness T₆₁₂ of the spacer layer 612A by forming the first electrode finger 604A to step up in the first, Z-axis direction to be farther from the outer surface 606 or step down in the first direction to be closer to the outer surface 606. FIG. 6B also shows a cross-section of the spacer layer 612B.

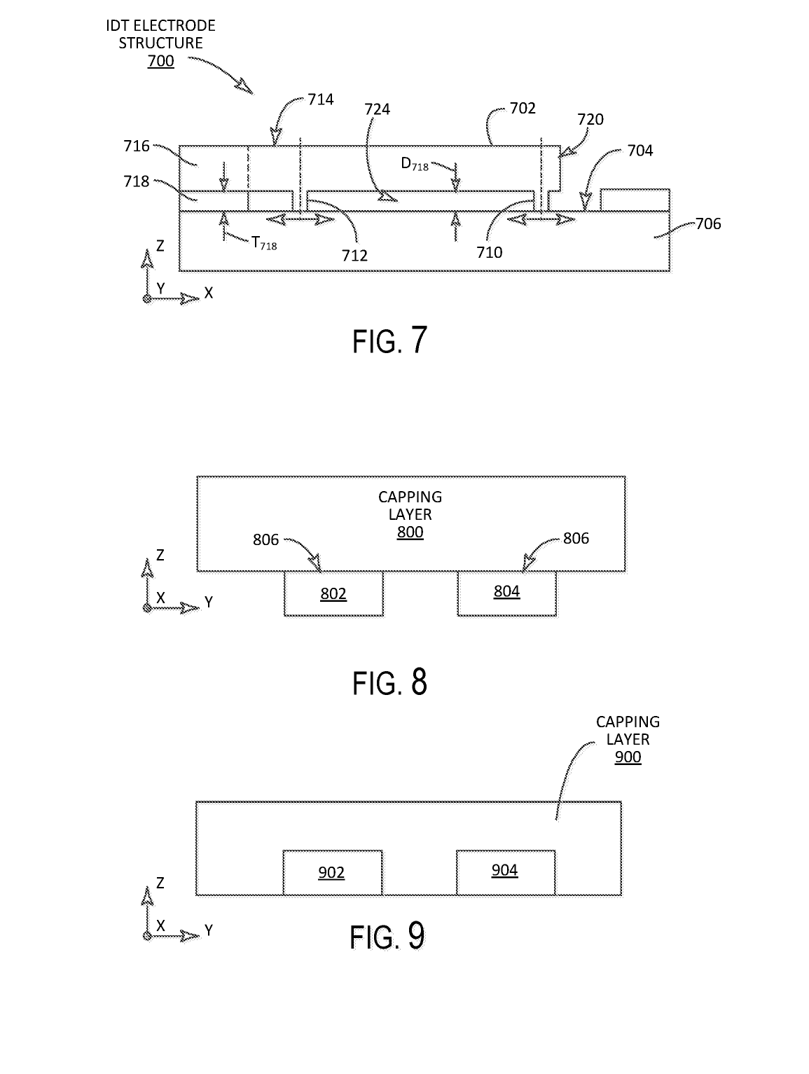

FIG. 7 is a cross-sectional side view of an IDT electrode structure 700 including a first electrode finger 702 spaced apart from an outer surface 704 of a piezoelectric layer 706 in a bridge configuration, in which one or more pillars 710, 712 supports the first electrode finger 702. In the example in FIG. 7, a first end 714 of the first electrode finger 702 is supported by a busbar 716, which is disposed on a spacer layer 718. At a second end 720, the first electrode finger 702 includes the first pillar 710 that extends in the first, Z-axis direction to the outer surface 704 to maintain a distance D₇₁₈ between first electrode finger 702 and the outer surface 704, where the distance D₇₁₈ is a height of a gap 724 that is based on a thickness T₇₁₈ of the spacer layer 718. In this example, the first electrode finger 702 further includes the second pillar 712 between the first end 714 and the second end 720 (e.g., between the first end 714 and the first pillar 710) to keep the first electrode finger 702 at the distance D₇₁₈ from the outer surface 704. In some examples, the second pillar 712, may be omitted. Alternatively, one or more additional pillars may be included for support along the first electrode finger 702, which may depend on a length, width, and/or thickness of the first electrode finger 702.

The first and second pillars, 710, 712 provide support but have a minimal footprint to minimize contact with the outer surface 704 to minimize energy loss and/or create spurious modes in a plate-mode micro-acoustic filter (not shown).

Options for formation of the first and second pillars 710, 712 include forming them of the same material (e.g., metal) as the first electrode finger 702 with a dielectric layer or coating (e.g., aluminum oxide (Al2O3) or silicon nitride (Si3N4) a few nanometers thick) to insulate the first electrode finger 702 from the outer surface 704. In this regard, fabrication may include a step of patterning the spacer layer 718 to expose the outer surface 704 in the area of the pillars 710, 712, depositing a film of a dielectric material on the outer surface 704 in those areas, and then forming the first electrode finger 702 thereon. When the spacer layer 718 is removed, to form the gap 724, the pillars 710, 712 remain to support the first electrode finger 702.

In an alternative process, the first and second pillars 710, 712 may be formed by oxidizing the spacer layer 718, which may be silicon dioxide (SiO2), only in the areas where the first and second pillars 710, 712 are to be formed. Such oxidation would create regions of amorphous SiO2 that would not be removed in the process of removing the spacer layer 718 and these regions of amorphous SiO2 would the first and second pillars 710, 712, supporting the first finger electrode 702.

FIG. 8 is a cross-sectional side view of a first example of a capping layer 800 disposed on a first IDT electrode structure 802 and a second IDT electrode structure 804 in a plate-mode micro-acoustic resonator as shown in FIGS. 6A and 6B or FIG. 7. The first and second IDT electrode structures 802 and 804 may be disposed on a piezoelectric layer in a micro-acoustic filter, as shown in FIGS. 4A, 4B, 6A, and 6B, to excite the piezoelectric layer in a plate mode. The capping layer 800 may be provided to protect the IDT electrode structures 802 and 804 from external contact and/or to provide support as an alternative to the support structures in FIGS. 6B and 7 for the first electrode fingers 604A and 702, respectively. For example, upper surfaces 806 of the first and second IDT electrode structures 802 and 804 may be coupled (e.g., adhesively) to the capping layer 800. The capping layer 800 may be disposed on and supported by the busbars 610A, 610B and 716, as shown in FIGS. 6A, 6B, and 7, for example (or extend from the busbars). The capping layer 800 may be provided for support and structural stability and to prevent movement of the electrode fingers 604A and 702, which are not in contact with the piezoelectric layer.

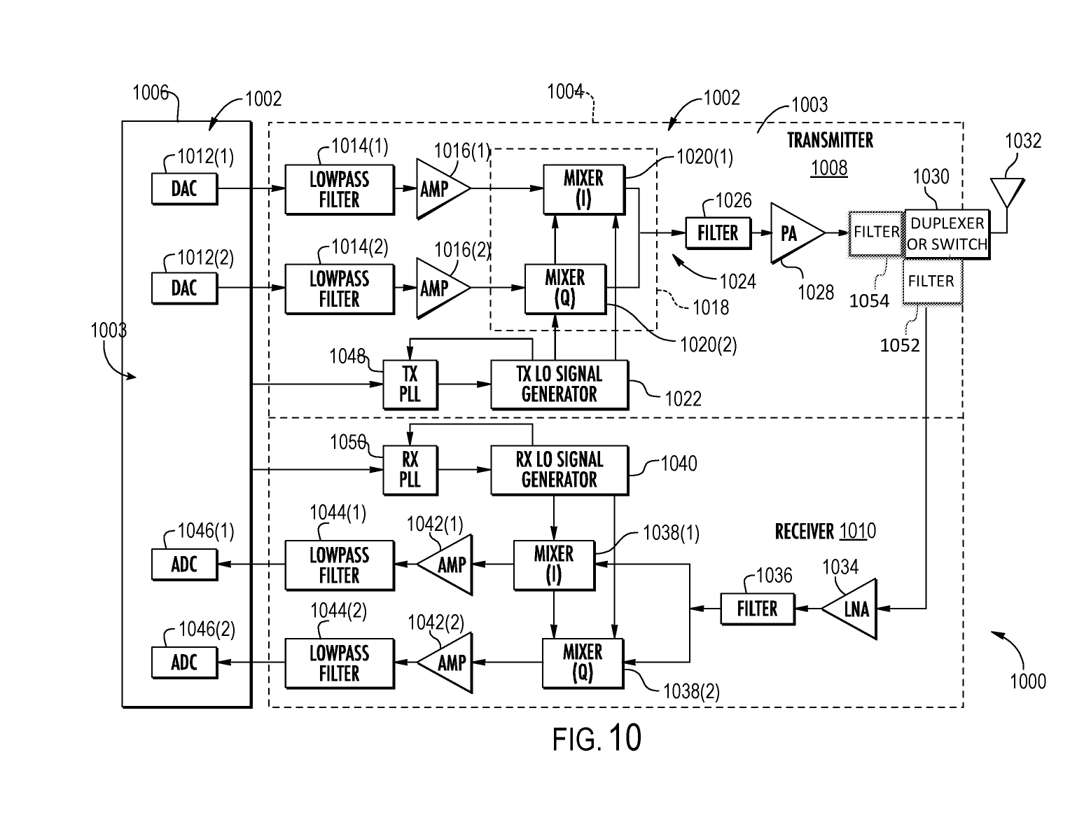

FIG. 9 is a cross-sectional side view of a second example of a capping layer 900 integrating IDT electrode structures 902 and 904 for use in a plate-mode acoustic resonator as shown in FIGS. 4A, 6A, and 6B. Integrating the IDT electrode structures 902 and 904 into the capping layer 900 may provide support and structural stability for the electrode fingers (not shown) of the IDT electrode structures 902 and 904 and to maintain a gap from an outer surface of a piezoelectric layer. Integrating the IDT electrode structures 902 and 904 into the capping layer 900 also provides an option for reducing a vertical height or thickness of a micro-acoustic filter compared to the capping layer 800 in FIG. 8.

The capping layers 800 and 900 may be formed of an insulating or dielectric material, for example. Any of the electrode structures 802 and 804 in FIG. 8 and 902 and 904 in FIG. 9 may be the electrode structures 402 and 600 in FIGS. 4A, 4B, 6A, and 6B.

Plate-mode micro-acoustic filters including IDT electrode structures including IDT electrode fingers spaced apart from an outer surface of a piezoelectric layer on a layer stack to reduce energy losses and spurious modes may be included in processor-based devices. Examples of such processor-based devices, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

FIG. 10 illustrates an exemplary wireless communications device 1000 that includes radio-frequency (RF) components formed from one or more ICs 1002, wherein any of the ICs 1002 may include IDT electrode structures including IDT electrode fingers spaced apart from an outer surface of a piezoelectric layer on a layer stack to reduce energy losses and spurious modes, as in any of the IDT electrode structures in FIGS. 4A, 4B, and 6A-9. The wireless communications device 1000 may include or be provided in any of the above-referenced devices, as examples. As shown in FIG. 10, the wireless communications device 1000 includes a transceiver 1004 and a data processor 1006. The data processor 1006 may include a memory to store data and program codes. The transceiver 1004 includes a transmitter 1008 and a receiver 1010 that support bi-directional communications. In general, the wireless communications device 1000 may include any number of transmitters 1008 and/or receivers 1010 for any number of communication systems and frequency bands. All or a portion of the transceiver 1004 may be implemented on one or more analog ICs, RF ICs (RFICs), mixed-signal ICs, etc.

The transmitter 1008 or the receiver 1010 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage and then from IF to baseband in another stage for the receiver 1010. In the direct-conversion architecture, a signal is frequency-converted between RF and baseband in one stage. The super-heterodyne and direct-conversion architectures may use different circuit blocks and/or have different requirements. In the wireless communications device 1000 in FIG. 10, the transmitter 1008 and the receiver 1010 are implemented with the direct-conversion architecture.

In the transmit path, the data processor 1006 processes data to be transmitted and provides I and Q analog output signals to the transmitter 1008. In the exemplary wireless communications device 1000, the data processor 1006 includes digital-to-analog converters (DACs) 1012(1), 1012(2) for converting digital signals generated by the data processor 1006 into the I and Q analog output signals (e.g., I and Q output currents) for further processing.

Within the transmitter 1008, lowpass filters 1014(1), 1014(2) filter the I and Q analog output signals, respectively, to remove undesired signals caused by the prior digital-to-analog conversion. Amplifiers (AMPs) 1016(1), 1016(2) amplify the signals from the lowpass filters 1014(1), 1014(2), respectively, and provide I and Q baseband signals. An upconverter 1018 upconverts the I and Q baseband signals with I and Q transmit (TX) local oscillator (LO) signals through mixers 1020(1), 1020(2) from a TX LO signal generator 1022 to provide an upconverted signal 1024. A filter 1026 filters the upconverted signal 1024 to remove undesired signals caused by the frequency up-conversion as well as noise in a receive frequency band. A power amplifier (PA) 1028 amplifies the upconverted signal 1024 from the filter 1026 to obtain the desired output power level and provides a transmit RF signal. The transmit RF signal is filtered by a transmit filter 1054 before being routed through a duplexer or switch 1030 and transmitted via an antenna 1032. The transmit filter 1054 may be a micro-acoustic filter configured to operate in a plate mode and including an interdigital transducer (IDT) electrode structure in which the electrode fingers are spaced apart from an outer surface of a piezoelectric layer on a layer stack, as shown in 4A, 4B, 6A, 6B, and 7.

In the receive path, the antenna 1032 receives signals transmitted by base stations and provides a received RF signal, which is routed through the duplexer or switch 1030 and receiver filter 1052 before being provided to a low noise amplifier (LNA) 1034. The receive filter 1052 may be a micro-acoustic filter configured to operate in a plate mode and including an interdigital transducer (IDT) electrode structure in which the electrode fingers are spaced apart from an outer surface of a piezoelectric layer on a layer stack, as shown in 4A, 4B, 6A, 6B, and 7, and may be included in or separate from the duplexer or switch 1030. The duplexer or switch 1030 is designed to operate with a specific receive (RX)-to-TX duplexer frequency separation, such that RX signals are isolated from TX signals. The received RF signal is amplified by the LNA 1034 and filtered by a filter 1036 to obtain a desired RF input signal. Down-conversion mixers 1038(1), 1038(2) mix the output of the filter 1036 with I and Q RX LO signals (i.e., LO_I and LO_Q) from an RX LO signal generator 1040 to generate I and Q baseband signals. The I and Q baseband signals are amplified by AMPs 1042(1), 1042(2) and further filtered by lowpass filters 1044(1), 1044(2) to obtain I and Q analog input signals, which are provided to the data processor 1006. In this example, the data processor 1006 includes analog-to-digital converters (ADCs) 1046(1), 1046(2) for converting the analog input signals into digital signals to be further processed by the data processor 1006.

In the wireless communications device 1000 of FIG. 10, the TX LO signal generator 1022 generates the I and Q TX LO signals used for frequency up-conversion, while the RX LO signal generator 1040 generates the I and Q RX LO signals used for frequency down-conversion. Each LO signal is a periodic signal with a particular fundamental frequency. A TX phase-locked loop (PLL) circuit 1048 receives timing information from the data processor 1006 and generates a control signal used to adjust the frequency and/or phase of the TX LO signals from the TX LO signal generator 1022. Similarly, an RX PLL circuit 1050 receives timing information from the data processor 1006 and generates a control signal used to adjust the frequency and/or phase of the RX LO signals from the RX LO signal generator 1040.

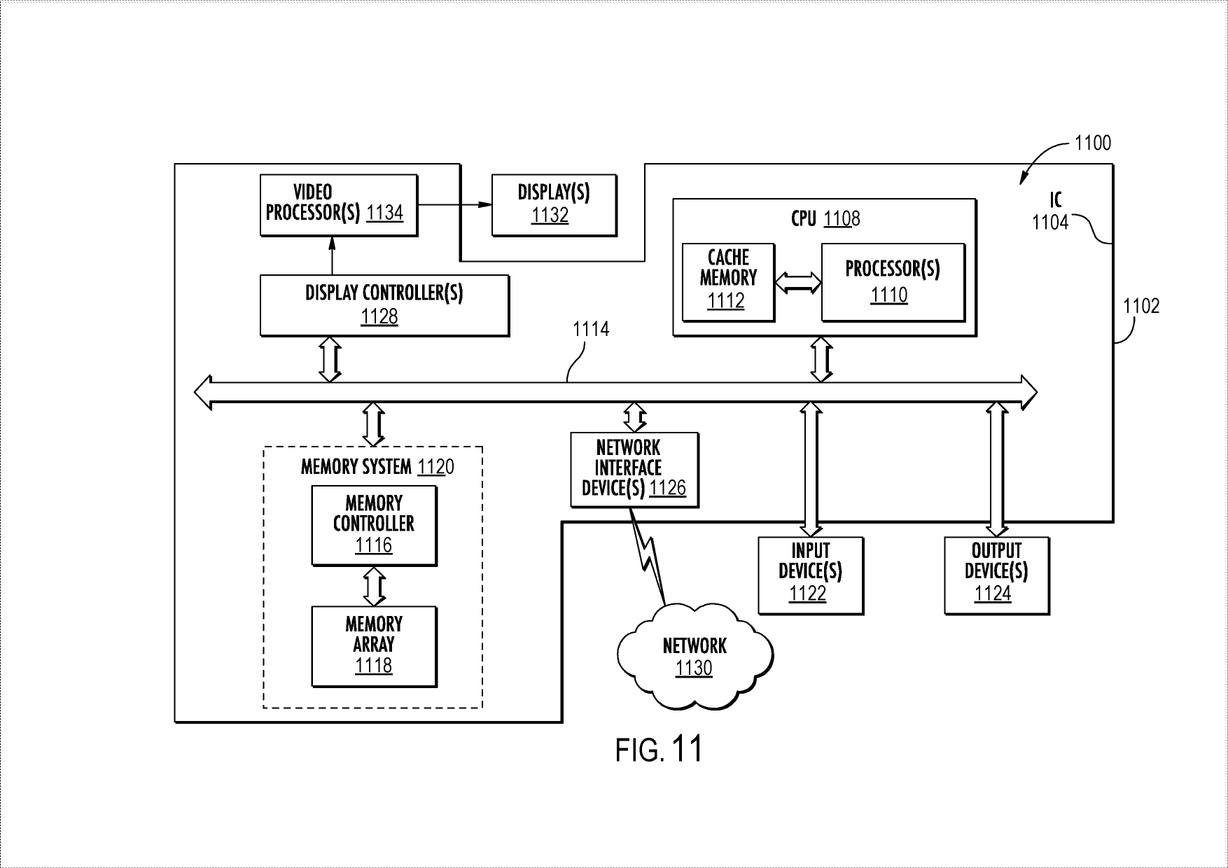

In this regard, FIG. 11 illustrates an example of a processor-based system 1100 that can include IDT electrode structures including IDT electrode fingers spaced apart from an outer surface of a piezoelectric layer on a layer stack to reduce energy losses and spurious modes, as in any of the IDT electrode structures in FIGS. 4A, 4B, and 6A-9. The processor-based system 1100 includes a central processing unit (CPU) 1108 that includes one or more processors 1110, which may also be referred to as CPU cores or processor cores. The CPU 1108 may have cache memory 1112 coupled to the CPU 1108 for rapid access to temporarily stored data. The CPU 1108 is coupled to a system bus 1114 and can intercouple master and slave devices included in the processor-based system 1100. As is well known, the CPU 1108 communicates with these other devices by exchanging address, control, and data information over the system bus 1114. For example, the CPU 1108 can communicate bus transaction requests to a memory controller 1116, as an example of a slave device. Although not illustrated in FIG. 11, multiple system buses 1114 could be provided, wherein each system bus 1114 constitutes a different fabric.

Other master and slave devices can be connected to the system bus 1114. As illustrated in FIG. 11, these devices can include a memory system 1120 that includes the memory controller 1116 and a memory array(s) 1118, one or more input devices 1122, one or more output devices 1124, one or more network interface devices 1126, and one or more display controllers 1128, as examples. The input device(s) 1122 can include any type of input device, including, but not limited to, input keys, switches, voice processors, etc. The output device(s) 1124 can include any type of output device, including, but not limited to, audio, video, other visual indicators, etc. The network interface device(s) 1126 can be any device configured to allow an exchange of data to and from a network 1130. The network 1130 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1126 can be configured to support any type of communications protocol desired.

The CPU 1108 may also be configured to access the display controller(s) 1128 over the system bus 1114 to control information sent to one or more displays 1132. The display controller(s) 1128 sends information to the display(s) 1132 to be displayed via one or more video processor(s) 1134, which processes the information to be displayed into a format suitable for the display(s) 1132. The display(s) 1132 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. The devices and components described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses: 1. A micro-acoustic filter comprising: a layer stack; a piezoelectric layer disposed on the layer stack and having an exposed surface opposite to the layer stack, wherein the piezoelectric layer has a crystalline structure operative to laterally excite a plate mode; and an interdigital transducer (IDT) electrode structure disposed over the exposed surface of the piezoelectric layer and comprising a first electrode structure comprising a plurality of first fingers spaced from the exposed surface and a second electrode structure comprising a plurality of second fingers spaced from the exposed surface. 2. The micro-acoustic filter of clause 1, wherein: the first electrode structure comprises a first busbar configured to support a first end of the plurality of first fingers cantilevered over the exposed surface of the piezoelectric layer; and the second electrode structure comprises a second busbar configured to support a first end of the plurality of second fingers cantilevered over the exposed surface of the piezoelectric layer. 3. The micro-acoustic filter of clause 1 or clause 2, wherein: the first electrode structure comprises a first busbar configured to support a first end of the plurality of first fingers; each first finger of the plurality of first fingers comprises a first support pillar at a second end of the first finger and extending in the second direction from the first finger to the exposed surface; the second electrode structure comprises a second busbar configured to support a first end of the plurality of second fingers; and each second finger of the plurality of second fingers comprises a second support pillar at a second end of the second finger and extending in the second direction from the second finger to the exposed surface. 4. The micro-acoustic filter of clause 3, wherein: each first finger of the plurality of first fingers comprises a third support pillar between the first end and the second end of the first finger and extending from the first finger to the exposed surface of the piezoelectric layer to support the first finger; and each second finger of the plurality of second fingers comprises a fourth support pillar between the first end and the second end of the second finger and extending from the second finger to the exposed surface of the piezoelectric layer to support the second finger. 5. The micro-acoustic filter of any of clause 1 to clause 4, the IDT electrode structure comprising: the first electrode structure configured to couple to a first voltage, wherein the plurality of first fingers extends in a first direction parallel to the exposed surface; and the second electrode structure configured to couple to a second voltage, wherein the plurality of second fingers extends in the first direction; wherein the plurality of first fingers and the plurality of second fingers are spaced from the exposed surface in a second direction orthogonal to the exposed surface. 6. The micro-acoustic filter of any of clause 1 to clause 5, the layer stack comprising first layers of a first material having a lower acoustic impedance alternating with second layers of a second material having a higher acoustic impedance on a substrate. 7. The micro-acoustic filter of clause 6, wherein a total number of the first layers of the first material and the second layers of the second material is in a range from four (4) to eight (8). 8. The micro-acoustic filter of any of clause 1 to clause 7, wherein the plurality of first fingers and the plurality of second fingers are spaced from the exposed surface in the second direction orthogonal to the exposed surface a distance in a range of one (1) nanometer (nm) to one hundred (100) nm. 9. The micro-acoustic filter of any of clause 1 to clause 8, wherein the plurality of first fingers and the plurality of second fingers are spaced from the exposed surface in the second direction orthogonal to the exposed surface a distance in a range of twenty-five (25) nm to thirty-five (35) nm. 10. The micro-acoustic filter of any of clause 2 to clause 9, further comprising: a first insulating layer disposed between the first busbar and the exposed surface of the piezoelectric layer; and a second insulating layer disposed between the second busbar and the exposed surface of the piezoelectric layer; wherein a distance between the plurality of first fingers and the exposed surface of the piezoelectric layer is based on a thickness of the first insulating layer in the second direction. 11. The micro-acoustic filter of any of clause 2 to clause 10, wherein: the plurality of first fingers of the first electrode structure is parallel to a second axis that is perpendicular to a first axis; a third axis is perpendicular to the first axis and the second axis; an orientation of the first axis, the second axis, and the third axis is relative to the crystalline structure of the piezoelectric layer as defined by Euler angles lambda, mu, and theta; and the piezoelectric layer comprises lithium niobate with the Euler angle lambda being approximately 0°, the Euler angle mu being approximately 32.5°, and the Euler angle theta being approximately 0°, or at least one symmetrical equivalent thereof. 12. The micro-acoustic filter of any of clause 1 to clause 11, further comprising an air gap between the plurality of first fingers and the exposed surface and between the plurality of second fingers and the exposed surface. 13. The micro-acoustic filter of any of clause 1 to clause 11, further comprising a capping layer disposed on the first electrode structure and the second electrode structure. 14. The micro-acoustic filter of clause 13, wherein the capping layer is coupled to and supports the plurality of first fingers and the plurality of second fingers. 15. The micro-acoustic filter of any of clause 1 to clause 14 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter. 16. A method of fabricating a micro-acoustic filter, comprising: forming a layer stack; forming a piezoelectric layer on the layer stack with an exposed surface opposite to the layer stack, wherein the piezoelectric layer has a crystalline structure operative to laterally excite a plate mode; and forming an interdigital transducer (IDT) electrode structure disposed on the exposed surface of the piezoelectric layer and comprising a first electrode structure comprising a plurality of first fingers spaced from the exposed surface and a second electrode structure comprising a plurality of second fingers spaced from the exposed surface. 17. The method of clause 16, further comprising: forming the plurality of first fingers of the first electrode structure extending in a first direction parallel to the exposed surface and spaced from the exposed surface in a second direction orthogonal to the exposed surface; and forming the plurality of second fingers of the second electrode structure extending in the first direction and spaced from the exposed surface in the second direction. 18. The method of clause 16 or clause 17, further comprising forming the plurality of first fingers and the plurality of second fingers at a distance in a range of twenty (20) nanometers (nm) to forty (40) nm in a second direction from the exposed surface. 19. The method of any of clause 16 to clause 18, further comprising forming the plurality of first fingers and the plurality of second fingers at a distance in a range of twenty-five (25) nm to thirty-five (35) nm in a second direction from the exposed surface. 20. The method of any of clause 16 to clause 19, wherein: forming the first electrode structure further comprises forming a first busbar to support a first end of the plurality of first fingers cantilevered over the exposed surface of the piezoelectric layer; and forming the second electrode structure further comprises forming a second busbar configured to support a first end of the plurality of second fingers cantilevered over the exposed surface of the piezoelectric layer. 21. The method of any of clause 17 to clause 20, wherein: forming the first electrode structure further comprises forming a first busbar configured to support a first end of the plurality of first fingers; forming the plurality of first fingers further comprises, for each first finger of the plurality of first fingers, forming a first support pillar at a second end of the first finger and extending in the second direction from the first finger to the exposed surface; forming the second electrode structure further comprises forming a second busbar configured to support a first end of the plurality of second fingers; and forming the plurality of second fingers further comprises, for each second finger of the plurality of second fingers, forming a second support pillar at a second end of the second finger and extending in the second direction from the second finger to the exposed surface. 22. The method of clause 21, wherein: forming each first finger of the plurality of first fingers further comprises forming a third support pillar between the first end and the second end of the first finger and extending in the second direction from the first finger to the exposed surface of the piezoelectric layer; and forming each second finger of the plurality of second fingers further comprises forming a fourth support pillar between the first end and the second end of the second finger and extending in the second direction from the second finger to the exposed surface of the piezoelectric layer. 23. The method of any of clause 17 to clause 22, further comprising: forming a first insulating layer between the first busbar and the exposed surface of the piezoelectric layer; and forming a second insulating layer between the second busbar and the exposed surface of the piezoelectric layer; wherein a distance in the second direction between the plurality of first fingers and the exposed surface of the piezoelectric layer is based on a thickness of the first insulating layer in the second direction. 24. The method of any of clause 17 to clause 23, wherein: the first direction of the plurality of first fingers of the first electrode structure is parallel to a second axis that is perpendicular to a first axis; a third axis is perpendicular to the first axis and the second axis; an orientation of the first axis, the second axis, and the third axis is relative to the crystalline structure of the piezoelectric layer as defined by Euler angles lambda, mu, and theta; and forming the piezoelectric layer comprises forming lithium niobate with the Euler angle lambda being approximately 0°, the Euler angle mu being approximately 32.5°, and the Euler angle theta being approximately 0° or at least one symmetrical equivalent thereof.

What is claimed is:

1. A micro-acoustic filter comprising:
a layer stack;
a piezoelectric layer disposed on the layer stack and having an exposed surface opposite to the layer stack, wherein the piezoelectric layer has a crystalline structure operative to laterally excite a plate mode; and
an interdigital transducer (IDT) electrode structure disposed over the exposed surface of the piezoelectric layer and comprising a first electrode structure comprising a plurality of first fingers spaced from the exposed surface and a second electrode structure comprising a plurality of second fingers spaced from the exposed surface.

2. The micro-acoustic filter of claim 1, wherein:
the first electrode structure comprises a first busbar configured to support a first end of the plurality of first fingers cantilevered over the exposed surface of the piezoelectric layer; and
the second electrode structure comprises a second busbar configured to support a first end of the plurality of second fingers cantilevered over the exposed surface of the piezoelectric layer.

3. The micro-acoustic filter of claim 1, wherein:
the first electrode structure comprises a first busbar configured to support a first end of the plurality of first fingers;
each first finger of the plurality of first fingers comprises a first support pillar at a second end of the first finger and extending from the first finger to the exposed surface;
the second electrode structure comprises a second busbar configured to support a first end of the plurality of second fingers; and
each second finger of the plurality of second fingers comprises a second support pillar at a second end of the second finger and extending from the second finger to the exposed surface.

4. The micro-acoustic filter of claim 3, wherein:
each first finger of the plurality of first fingers comprises a third support pillar between the first end and the second end of the first finger and extending from the first finger to the exposed surface of the piezoelectric layer to support the first finger; and
each second finger of the plurality of second fingers comprises a fourth support pillar between the first end and the second end of the second finger and extending from the second finger to the exposed surface of the piezoelectric layer to support the second finger.

5. The micro-acoustic filter of claim 1, the IDT electrode structure comprising:
the first electrode structure configured to couple to a first voltage, wherein the plurality of first fingers extends in a first direction parallel to the exposed surface; and
the second electrode structure configured to couple to a second voltage, wherein the plurality of second fingers extends in the first direction;
wherein the plurality of first fingers and the plurality of second fingers are spaced from the exposed surface in a second direction orthogonal to the exposed surface.

6. The micro-acoustic filter of claim 1, the layer stack comprising first layers of a first material having a lower acoustic impedance alternating with second layers of a second material having a higher acoustic impedance on a substrate.

7. The micro-acoustic filter of claim 6, wherein a total number of the first layers of the first material and the second layers of the second material is in a range from four (4) to eight (8).

8. The micro-acoustic filter of claim 5, wherein the plurality of first fingers and the plurality of second fingers are spaced from the exposed surface in the second direction orthogonal to the exposed surface a distance in a range of one nanometer (nm) to one hundred (100) nm.

9. The micro-acoustic filter of claim 5, wherein the plurality of first fingers and the plurality of second fingers are spaced from the exposed surface in the second direction orthogonal to the exposed surface a distance in a range of twenty-five (25) nm to thirty-five (35) nm.

10. The micro-acoustic filter of claim 2, further comprising:
a first insulating layer disposed between the first busbar and the exposed surface of the piezoelectric layer; and
a second insulating layer disposed between the second busbar and the exposed surface of the piezoelectric layer;
wherein a distance between the plurality of first fingers and the exposed surface of the piezoelectric layer is based on a thickness of the first insulating layer.

11. The micro-acoustic filter of claim 7, wherein:
the plurality of first fingers of the first electrode structure is parallel to a second axis that is perpendicular to a first axis;
a third axis is perpendicular to the first axis and the second axis;
an orientation of the first axis, the second axis, and the third axis is relative to the crystalline structure of the piezoelectric layer as defined by Euler angles lambda, mu, and theta; and
the piezoelectric layer comprises lithium niobate with the Euler angle lambda being approximately 0°, the Euler angle mu being approximately 32.5°, and the Euler angle theta being approximately 0°, or at least one symmetrical equivalent thereof.

12. The micro-acoustic filter of claim 1, further comprising an air gap between the plurality of first fingers and the exposed surface and between the plurality of second fingers and the exposed surface.

13. The micro-acoustic filter of claim 1, further comprising a capping layer disposed on the first electrode structure and the second electrode structure.

14. The micro-acoustic filter of claim 13, wherein the capping layer is coupled to and supports the plurality of first fingers and the plurality of second fingers.

15. The micro-acoustic filter of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

16. A method of fabricating a micro-acoustic filter, comprising:
forming a layer stack;
forming a piezoelectric layer on the layer stack with an exposed surface opposite to the layer stack, wherein the piezoelectric layer has a crystalline structure operative to laterally excite a plate mode; and
forming an interdigital transducer (IDT) electrode structure disposed on the exposed surface of the piezoelectric layer and comprising a first electrode structure comprising a plurality of first fingers spaced from the exposed surface and a second electrode structure comprising a plurality of second fingers spaced from the exposed surface.

17. The method of claim 16, further comprising:
forming the plurality of first fingers of the first electrode structure extending in a first direction parallel to the exposed surface and spaced from the exposed surface in a second direction orthogonal to the exposed surface; and
forming the plurality of second fingers of the second electrode structure extending in the first direction and spaced from the exposed surface in the second direction.

18. The method of claim 16, further comprising forming the plurality of first fingers and the plurality of second fingers at a distance in a range of twenty (20) nanometers (nm) to forty (40) nm in a second direction from the exposed surface.

19. The method of claim 16, further comprising forming the plurality of first fingers and the plurality of second fingers at a distance in a range of twenty-five (25) nm to thirty-five (35) nm in a second direction from the exposed surface.

20. The method of claim 16, wherein:
forming the first electrode structure further comprises forming a first busbar to support a first end of the plurality of first fingers cantilevered over the exposed surface of the piezoelectric layer; and
forming the second electrode structure further comprises forming a second busbar configured to support a first end of the plurality of second fingers cantilevered over the exposed surface of the piezoelectric layer.
